(19) United States
(12) Patent Application Publication
(10) Pub. No.: US 2008/0036362 A1
(43) Pub. Date: Feb. 14, 2008

(54) Light-Emitting Device, Light-Emitting Module, Display Unit, Lighting Unit and Method for Manufacturing Light-Emitting Device

(75) Inventors: Noriyasu Tanimoto, Osaka (JP); Kunihiko Obara, Kagoshima (JP); Hideo Nagai, Osaka (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Kadoma-shi, Osaka (JP)

(21) Appl. No.: 11/571,550

(22) PCT Filed: Nov. 10, 2005
(86) PCT No.: PCT/JP05/21076

§ 371 Date: Jan. 2, 2007

(30) Foreign Application Priority Data
Nov. 22, 2004 (JP) 2004-337824

(51) Int. Cl. H01L 33/00; H01L 21/02

(52) U.S. Cl. 313/498; 438/22; 257/E33.001

(57) ABSTRACT

A light-emitting device (1) includes the following: a substrate (10) that includes a base material (11) and a first conductor pattern (12) formed on a principal surface (11a) of the base material (11); a semiconductor light-emitting element (14) that is mounted on the first conductor pattern (12); and a phosphor layer (15) that is formed on the substrate (10) to cover the semiconductor light-emitting element (14) and emits fluorescence as a result of absorption of light emitted from the semiconductor light-emitting element (14). A side (15a) of the phosphor layer (15) and a side (10a) of the substrate (10) are connected continuously. The light-emitting device (1) can suppress color non-uniformity of light to be produced.

### TECHNICAL FIELD

The present invention relates to a light-emitting device, and a light-emitting module, a display unit and a lighting unit that use the light-emitting device, and a method for manufacturing the light-emitting device.

### BACKGROUND ART

A GaN light-emitting diode (referred to as “LED” in the following) is known as a semiconductor light-emitting element including a semiconductor multilayer film. In particular, a blue LED for emitting blue light is combined with a phosphor that emits yellow light or red light by excitation of the blue light and can be used as a white LED for emitting white light (e.g., JP 2001-15817 A). A white LED also can be formed by combining several types of LEDs for emitting ultraviolet light or near-ultraviolet light and phosphors for emitting fluorescence in a wavelength region longer than blue. The white LED can have a longer life compared with incandescent lamps or halogen lamps and thus is expected to replace the existing lighting sources in the future.

FIG. 24 is a cross-sectional view showing a light-emitting module including a white LED that has been proposed in JP 2001-15817 A. As shown in FIG. 24, a light-emitting module 1000 includes the following: a main substrate 1001; a sub-mount substrate 1002 mounted on the main substrate 1001; a blue LED 1004 mounted on a conductor pattern 1003 that is provided on the sub-mount substrate 1002; a phosphor layer 1005 formed on the sub-mount substrate 1002 to cover the blue LED 1004; and a sealing resin layer 1006 formed on the main substrate 1001 to cover the phosphor layer 1005. The phosphor layer 1005 absorbs blue light emitted from the blue LED 1004 and emits yellow fluorescence. In other words, the blue LED 1004 and the phosphor layer 1005 constitute a white LED.

A terminal 1010 is formed on the main substrate 1001. A wire pad 1011 is formed on the conductor pattern 1003. The terminal 1010 and the wire pad 1011 are connected electrically by a bonding wire 1012.

When light is produced by the light-emitting module 1000 with this configuration, electricity is supplied from the terminal 1010 to the blue LED 1004 through the bonding wire 1012, the wire pad 1011, and the conductor pattern 1003. Accordingly, blue light having a wavelength of, e.g., 460 nm is emitted from the blue LED 1004. The phosphor layer 1005 absorbs this blue light and emits yellow light. Then, the yellow light emitted from the phosphor layer 1005 and the blue light that is generated by the blue LED 1004 and passes through the phosphor layer 1005 are mixed and can be taken out as white light.

The phosphor layer 1005 is formed generally by printing a phosphor paste including a phosphor with screen printing. Therefore, the edge of the phosphor layer 1005 may be deformed due to flow of the phosphor paste after printing (this phenomenon is referred to as “edge deformation” in the following). The edge deformation results in color non-uniformity of light to be produced. For this reason, the sides of the phosphor layer 1005 other than the side 1005a that faces the wire pad 1011 are scraped evenly with a rotating blade or the like. However, the side 1005a cannot be scraped because of the presence of the wire pad 1011. Consequently, shape unevenness of the phosphor layer 1005 caused by the edge deformation remains in a stepped portion 1002a on the sub-mount substrate 1002 in which the wire pad 1011 is formed. Thus, the light produced by the light-emitting module 1000 of JP 2001-15817 A may cause color non-uniformity.

### DISCLOSURE OF INVENTION

With the foregoing in mind, the present invention provides a light-emitting device that can suppress color non-uniformity of light to be produced, and a light-emitting module, a display unit and a lighting unit that use the light-emitting device, and a method for manufacturing the light-emitting device.

A light-emitting device of the present invention includes the following: a substrate that includes a base material and a first conductor pattern formed on one principal surface of the base material; a semiconductor light-emitting element that is mounted on the first conductor pattern; and a phosphor layer that is formed on the substrate to cover the semiconductor light-emitting element and emits fluorescence as a result of absorption of light emitted from the semiconductor light-emitting element. A side of the phosphor layer and a side of the substrate are connected continuously.

In this case, “a side of the phosphor layer and a side of the substrate are connected continuously” means that no stepped portion is present along the entire boundary between the sides of the phosphor layer and the sides of the substrate.

A light-emitting module of the present invention includes the above light-emitting device and a main substrate on which the light-emitting module is mounted. A display unit and a lighting unit of the present invention use the above light-emitting module as a light source.

A method for manufacturing a light-emitting device of the present invention includes the following: mounting a semiconductor light-emitting element on a conductor pattern of a substrate that includes a base material, with the conductor pattern being formed on one principal surface of the base material; forming a phosphor layer that emits fluorescence as a result of absorption of light emitted from the semiconductor light-emitting element on the substrate so as to cover the semiconductor light-emitting element; and cutting out the phosphor layer and the substrate at the same time so that a side of the phosphor layer and a side of the substrate are connected continuously.

### BRIEF DESCRIPTION OF DRAWINGS

FIG. 1A is a cross-sectional view showing a light-emitting device of Embodiment 1 of the present invention. FIG. 1B is a schematic top view showing the arrangement of components of the light-emitting device of Embodiment 1 of the present invention. FIG. 1C is a schematic bottom view showing the arrangement of components of the light-emitting device of Embodiment 1 of the present invention.

FIGS. 2A to 2G are cross-sectional views showing the processes of a method for manufacturing the light-emitting device of Embodiment 1 of the present invention.

FIG. 3A to 3D are cross-sectional views showing the processes of the method for manufacturing the light-emitting device of Embodiment 1 of the present invention.

FIG. 4A is a cross-sectional view showing a light-emitting device of Embodiment 2 of the present invention. FIG. 4B is a schematic top view showing the arrangement of components of the light-emitting device of Embodiment 2 of the present invention. FIG. 4C is a schematic bottom view showing the arrangement of components of the light-emitting device of Embodiment 2 of the present invention.

FIGS. 5A to 5G are cross-sectional views showing the processes of a method for manufacturing the light-emitting device of Embodiment 2 of the present invention.

FIGS. 6A to 6D are cross-sectional views showing the processes of the method for manufacturing the light-emitting device of Embodiment 2 of the present invention.

FIG. 7 is a cross-sectional view showing a light-emitting device of Embodiment 3 of the present invention.

FIGS. 8A to 8E are cross-sectional views showing the processes of a method for manufacturing the light-emitting device of Embodiment 3 of the present invention.

FIGS. 9A to 9D are cross-sectional views showing the processes of the method for manufacturing the light-emitting device of Embodiment 3 of the present invention.

FIG. 10A is a schematic perspective view showing a light-emitting device of Embodiment 4 of the present invention. FIG. 10B is a schematic top view showing the arrangement of components of the light-emitting device of Embodiment 4 of the present invention.

FIG. 11 is a plan view for explaining some processes of a method for manufacturing the light-emitting device of Embodiment 4 of the present invention.

FIG. 12 is a cross-sectional view showing a modified example of the light-emitting device of Embodiment 1 of the present invention.

FIG. 13 is a cross-sectional view showing a modified example of the light-emitting device of Embodiment 1 of the present invention.

FIG. 14 is a cross-sectional view showing a modified example of the light-emitting device of Embodiment 1 of the present invention.

FIG. 15 is a cross-sectional view showing a light-emitting module of Embodiment 5 of the present invention.

FIG. 16 is a cross-sectional view showing a light-emitting module of Embodiment 6 of the present invention.

FIG. 17 is a cross-sectional view showing a light-emitting module of Embodiment 7 of the present invention.

FIG. 18 is a cross-sectional view showing an example of a light-emitting module of the present invention.

FIG. 19 is a perspective view showing an image display of Embodiment 8 of the present invention.

FIG. 20 is a perspective view showing a digital display of Embodiment 9 of the present invention.

FIG. 21 is a perspective view showing a desktop lamp of Embodiment 10 of the present invention.

FIG. 22 is a schematic top view showing the arrangement of components of a light-emitting device of an embodiment of the present invention.

FIG. 23 is a schematic top view showing the arrangement of components of a light-emitting device of an embodiment of the present invention.

FIG. 24 is a cross-sectional view showing a conventional light-emitting module.

### DESCRIPTION OF THE INVENTION

The light-emitting device of the present invention includes the following: a substrate that includes a base material and a first conductor pattern formed on one principal surface of the base material; a semiconductor light-emitting element that is mounted on the first conductor pattern; and a phosphor layer that is formed on the substrate to cover the semiconductor light-emitting element and emits fluorescence as a result of absorption of light emitted from the semiconductor light-emitting element.

The material of the base material is not particularly limited, and a ceramic material such as Al₂O₃ or AlN, or a semiconductor material such as Si can be used. The thickness of the base material may be, e.g., about 0.1 to 1 mm.

The material of the first conductor pattern also is not particularly limited, and any general conductive material (such as copper, aluminum, or gold) can be used. The thickness of the first conductor pattern may be, e.g., about 0.5 to 10 μm.

The semiconductor light-emitting element may have a diode structure of a blue LED. Specifically, a suitable LED includes a semiconductor multilayer film in which a first conductive-type layer, a light-emitting layer, and a second conductive-type layer are deposited in this order. The “first conductive-type” indicates p-type or n-type, and the “second conductive-type” indicates the conductive type opposite to the first conductive type. For example, when the first conductive-type layer is a p-type semiconductor layer, the second conductive-type layer is an n-type semiconductor layer. The first conductive-type layer may be, e.g., a p-GaN layer (p-type semiconductor layer) or n-GaN layer (n-type semiconductor layer). As the second conductive-type layer, e.g., the p-GaN layer (p-type semiconductor layer) or n-GaN layer (n-type semiconductor layer) also can be used. It is preferable to use a material that can emit light having a wavelength of 450 to 470 nm for the light-emitting layer. A specific example of the light-emitting layer may be an InGaN/GaN quantum well light-emitting layer. Moreover, a material that can emit light having a wavelength of not more than 410 nm may be used for the light-emitting layer. The thicknesses of the p-type semiconductor layer, the light-emitting layer, and the n-type semiconductor layer may be, e.g., 0.1 to 0.5 μm, 0.01 to 0.1 μm, and 0.5 to 3 μm, respectively.

The light-emitting device of the present invention may include a single crystal substrate such as a GaN substrate used in crystal growth of the semiconductor multilayer film. The semiconductor multilayer film also may be formed by depositing the n-type semiconductor layer, the light-emitting layer, and the p-type semiconductor layer in this order on a sapphire substrate by crystal growth, and subsequently removing the sapphire substrate.

The phosphor layer includes a phosphor that absorbs light emitted from the semiconductor light-emitting element and emits fluorescence (e.g., yellow light or red light). Examples of the phosphor for emitting yellow light include (Sr, Ba)₂SiO₄: Eu²⁺ and (Y, Gd)₃Al₅O₁₂: Ce³⁺. Examples of the phosphor for emitting red light include (Ca, Sr)S:Eu²⁺ and Sr₂Si₅N₈:Eu²⁺. The average thickness of the phosphor layer may be, e.g., about 0.03 to 1 mm.

In the light-emitting device of the present invention, a side of the phosphor layer and a side of the substrate are connected continuously. That is, no stepped portion is present in the entire boundary between the sides of the phosphor layer and the sides of the substrate. This eliminates shape unevenness of the phosphor layer caused by the edge deformation. Thus, the light-emitting device of the present invention can suppress color non-uniformity of light to be produced. Moreover, it is not necessary to consider the permeation of a phosphor paste onto the first conductor pattern, which extends the range of choices of a paste material (silicone resin or the like) for the phosphor paste. Therefore, a paste material having high heat resistance or high light resistance can be used regardless of its viscosity.

In the light-emitting device of the present invention, the substrate further may include a second conductor pattern formed on the other principal surface of the base material that is opposite to the principal surface provided with the first conductor pattern, and via conductors formed in the thickness direction of the base material for electrically connecting the first conductor pattern and the second conductor pattern. With this configuration, a bonding wire is not required and neither is a region for arranging the bonding wire, thus reducing the size of an optical system. Moreover, it is possible to avoid a problem of using the bonding wire (e.g., breaking or failure of the bonding wire due to thermal stress), so that the reliability of electric connection can be improved. The material or thickness of the second conductor pattern may be the same as the first conductor pattern. The material of the via conductors may be, e.g., a conductive material such as copper, tungsten, aluminum, or gold.

In the above light-emitting device including the second conductor pattern and the via conductors, the via conductors may be formed along the sides of the base material. This configuration can increase the volume of the via conductors, and therefore further can improve the reliability of electric connection between the first conductor pattern and the second conductor pattern.

In the above light-emitting device including the second conductor pattern and the via conductors, the base material may include a first conductive-type region that is in contact with the first conductor pattern, and a second conductive-type region that is in contact with both the first conductive-type region and the second conductor pattern. The first conductive-type region and the second conductive-type region constitute a so-called Zener diode. Therefore, if a high voltage such as static electricity is applied to the semiconductor light-emitting element, it can be protected by the Zener diode. The conductive type of each of the first and second conductive-type regions may be determined appropriately depending on the conductive-type layers of the semiconductor light-emitting element that are connected to the first and second conductor patterns, respectively. The semiconductor material for each of the first and second conductive-type regions is not particularly limited, and a general semiconductor material such as Si can be used.

The light-emitting module of the present invention includes the above light-emitting device and a main substrate on which the light-emitting device is mounted. The main substrate may be, e.g., a ceramic substrate, a metal substrate, or a laminated substrate of a metal layer and an electric insulating layer (e.g., a composite sheet including an inorganic filler and a thermosetting resin). The thickness of the main substrate may be, e.g., 1 to 2 mm. The number of light-emitting devices mounted on the main substrate is not particularly limited, and may be determined appropriately depending on the desired amount of light. The display unit and the lighting unit of the present invention use the light-emitting module as a light source. Accordingly, each of the light-emitting module, the display unit, and the lighting unit of the present invention includes the light-emitting device of the present invention and thus can suppress color non-uniformity of light to be produced.

The method for manufacturing a light-emitting device of the present invention is suitable for the light-emitting device of the present invention. Therefore, the materials or the like of the following components are the same as those of the light-emitting device as described above.

In the manufacturing method of a light-emitting device of the present invention, first, a substrate that includes a base material and a conductor pattern formed on one principal surface of the base material is used, and a semiconductor light-emitting element is mounted on the conductor pattern, e.g., by flip chip bonding.

Next, a phosphor layer that emits fluorescence as a result of absorption of light emitted from the semiconductor light-emitting element is formed on the substrate so as to cover the semiconductor light-emitting element. For example, a phosphor paste including a phosphor and a resin composition that contains a silicone resin or the like may be used to form the phosphor layer by screen printing.

Then, the phosphor layer and the substrate are cut out at the same time with a rotating blade or the like. This method easily can provide the light-emitting device of the present invention in which a side of the phosphor layer and a side of the substrate are connected continuously. Hereinafter, embodiments of the present invention will be described in detail.

### Embodiment 1

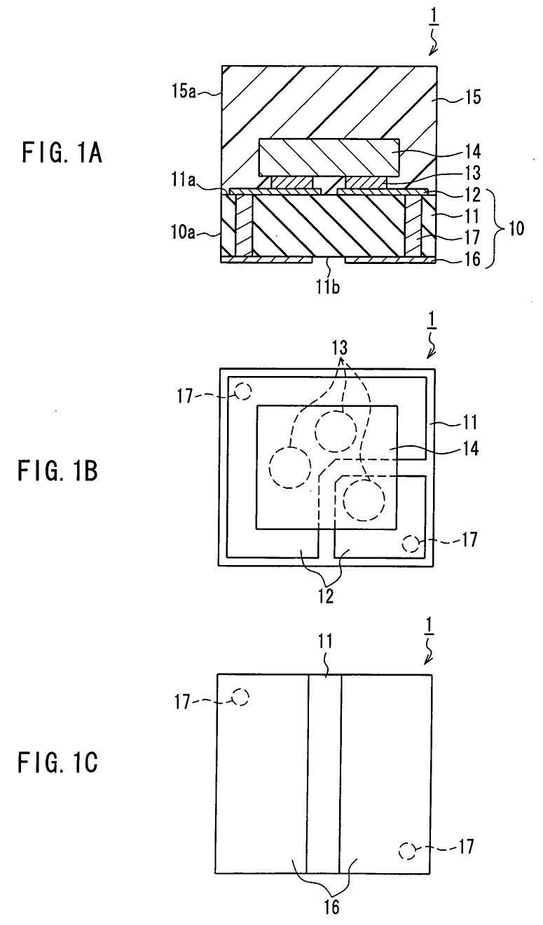

A light-emitting device of Embodiment 1 of the present invention will be described with reference to the drawings. FIG. 1 illustrates the light-emitting device of Embodiment 1: FIG. 1A is a cross-sectional view showing the light-emitting device of Embodiment 1; FIG. 1B is a schematic top view showing the arrangement of components of the light-emitting device of Embodiment 1; and FIG. 1C is a schematic bottom view showing the arrangement of components of the light-emitting device of Embodiment 1. FIG. 1B does not include a phosphor layer.

As shown in FIGS. 1A to 1C, the light-emitting device 1 includes the following: a substrate 10 that includes a base material 11 and a first conductor pattern 12 formed on a principal surface 11a of the base material 11; a semiconductor light-emitting element 14 that is mounted on the first conductor pattern 12 via bumps 13; and a phosphor layer 15 that is formed on the substrate 10 to cover the semiconductor light-emitting element 14 and emits fluorescence as a result of absorption of light emitted from the semiconductor light-emitting element 14.

The substrate 10 further includes a second conductor pattern 16 and via conductors 17. The second conductor pattern 16 is formed on a principal surface 11b of the base material 11 that is opposite to the principal surface 11a. The via conductors 17 are formed in the thickness direction of the base material 11 for electrically connecting the first conductor pattern 12 and the second conductor pattern 16.

In the light-emitting device 1, a side 15a of the phosphor layer 15 and a side 10a of the substrate 10 are connected continuously, thereby eliminating shape unevenness of the phosphor layer 15 caused by the edge deformation. Thus, the light-emitting device 1 can suppress color non-uniformity of light to be produced.

When light is produced by the light-emitting device 1 with this configuration, electricity is supplied from the second conductor pattern 16 to the semiconductor light-emitting element 14 through the via conductors 17, the first conductor pattern 12, and the bumps 13. Accordingly, blue light having a wavelength of, e.g., 460 nm is emitted from the semiconductor light-emitting element 14. The phosphor layer 15 absorbs this blue light and emits, e.g., yellow light or red light. Then, the yellow or red light emitted from the phosphor layer 15 and the blue light that is generated by the semiconductor light-emitting element 14 and passes through the phosphor layer 15 are mixed and can be taken out as white light.

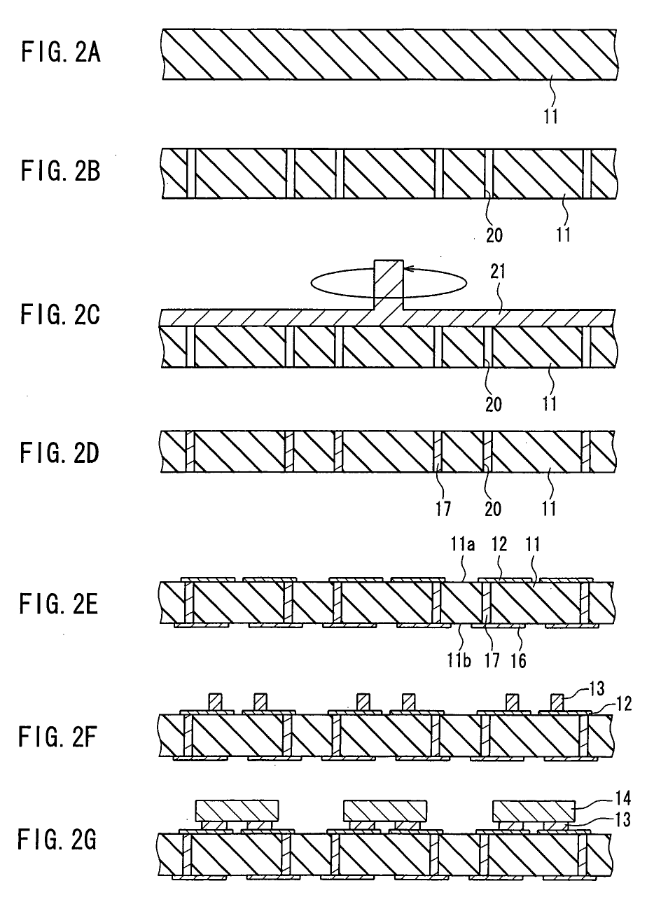

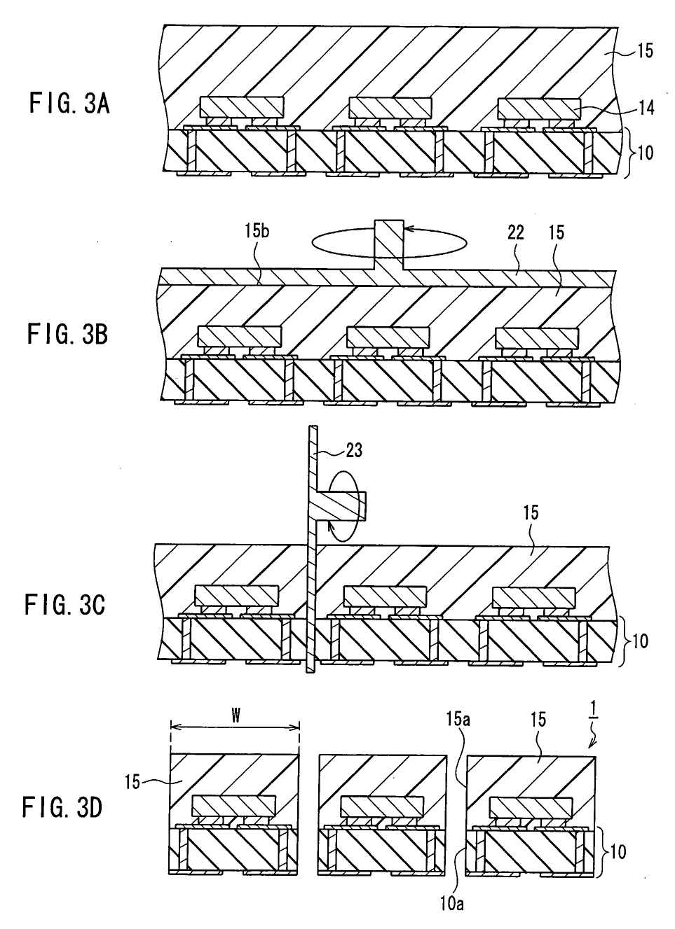

Next, a method for manufacturing the light-emitting device 1 of Embodiment 1 of the present invention will be described by appropriately referring to the drawings. FIGS. 2A to 2G and 3A to 3D are cross-sectional views showing the processes of a method for manufacturing the light-emitting device 1 of Embodiment 1. The same components as those in FIG. 1 are denoted by the same reference numerals, and the explanation will not be repeated.

First, the base material 11 is prepared in FIG. 2A. As the base material 11, e.g., a ceramic sheet having a thickness of about 500 μm without sintering can be used. Then, via holes 20 are formed in the base material 11 by punching or the like, as shown in FIG. 2B. The diameter of the via holes 20 may be, e.g., about 100 to 200 μm. Subsequently, the base material 11 is sintered at about 1600 to 1800° C.

Next, as shown in FIG. 2C, the base material 11 is polished with a rotary grinder 21 or the like. For example, the polishing may be performed to the extent that the thickness of the base material 11 is about 100 to 300 μm.

As shown in FIG. 2D, the inside of the via holes 20 is plated with a metallic material such as copper, aluminum or gold, thereby forming the via conductors 17.

As shown in FIG. 2E, the first conductor pattern 12 and the second conductor pattern 16, each of which is connected electrically to the via conductors 17, are formed on the principal surfaces 11a and 11b of the base material 11 by using a well-known photolithography technique.

As shown in FIG. 2F, the bumps 13 made of, e.g., gold are formed on the first conductor pattern 12. Then, as shown in FIG. 2G, the semiconductor light-emitting elements 14 are mounted on the bumps 13.

Next, as shown in FIG. 3A, the phosphor layer 15 having an average thickness of about 500 μm is formed on the substrate 10 to cover the semiconductor light-emitting elements 14. A phosphor paste including a phosphor that emits fluorescence as a result of absorption of light emitted from the semiconductor light-emitting elements 14 and a resin composition that contains a silicone resin or the like may be used to form the phosphor layer 15 by screen printing.

As shown in FIG. 3B, an upper surface 15b of the phosphor layer 15 is polished with a rotary grinder 22 or the like. For example, the polishing may be performed to the extent that the thickness of the phosphor layer 15 is about 200 to 300 μm.

Then, the phosphor layer 15 and the substrate 10 are cut out at the same time with a rotating blade 23 or the like, as shown in FIG. 3C. Thus, individual light-emitting devices 1 are provided, as shown in FIG. 3D. This method easily can provide the light-emitting device 1 in which the side 15a of the phosphor layer 15 and the side 10a of the substrate 10 are connected continuously. Moreover, the width W of the phosphor layer 15 can be controlled easily by changing the thickness of the cutting edge of the rotating blade 23. The width W of the phosphor layer 15 may be, e.g., about 500 to 600 μm.

### Embodiment 2

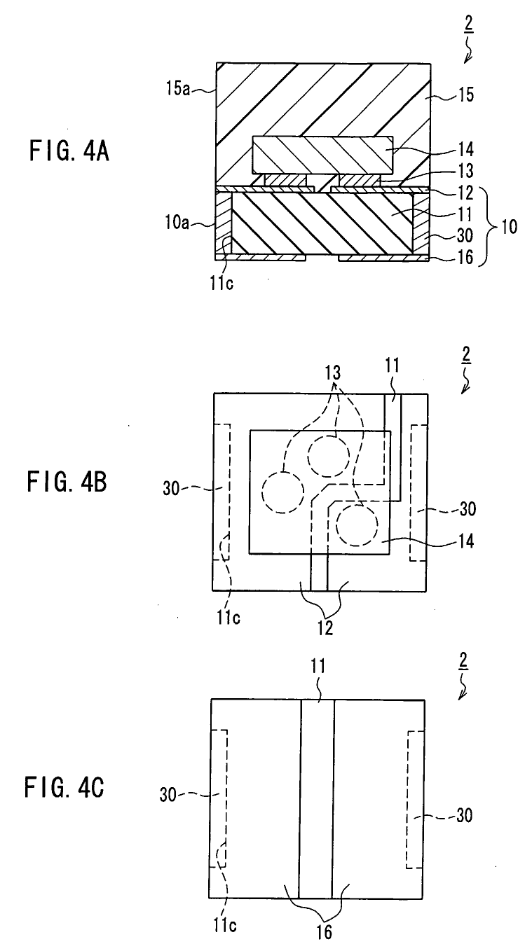

A light-emitting device of Embodiment 2 of the present invention will be described with reference to the drawings. FIG. 4 illustrates the light-emitting device of Embodiment 2: FIG. 4A is a cross-sectional view showing the light-emitting device of Embodiment 2; FIG. 4B is a schematic top view showing the arrangement of components of the light-emitting device of Embodiment 2; and FIG. 4C is a schematic bottom view showing the arrangement of components of the light-emitting device of Embodiment 2. FIG. 4B does not include a phosphor layer. The same components as those in FIG. 1 are denoted by the same reference numerals, and the explanation will not be repeated.

The light-emitting device 2 of Embodiment 2 differs from the light-emitting device 1 of Embodiment 1 only in the locations of the via conductors. As shown in FIGS. 4A to 4C, via conductors 30 of the light-emitting device 2 are formed along sides 11c of the base material 11. This configuration can increase the volume of the via conductors 30, and therefore further can improve the reliability of electric connection between the first conductor pattern 12 and the second conductor pattern 16.

Like the light-emitting device 1 of Embodiment 1, a side 15a of the phosphor layer 15 and a side 10a of the substrate 10 are connected continuously in the light-emitting device 2. Thus, the light-emitting device 2 also can suppress color non-uniformity of light to be produced.

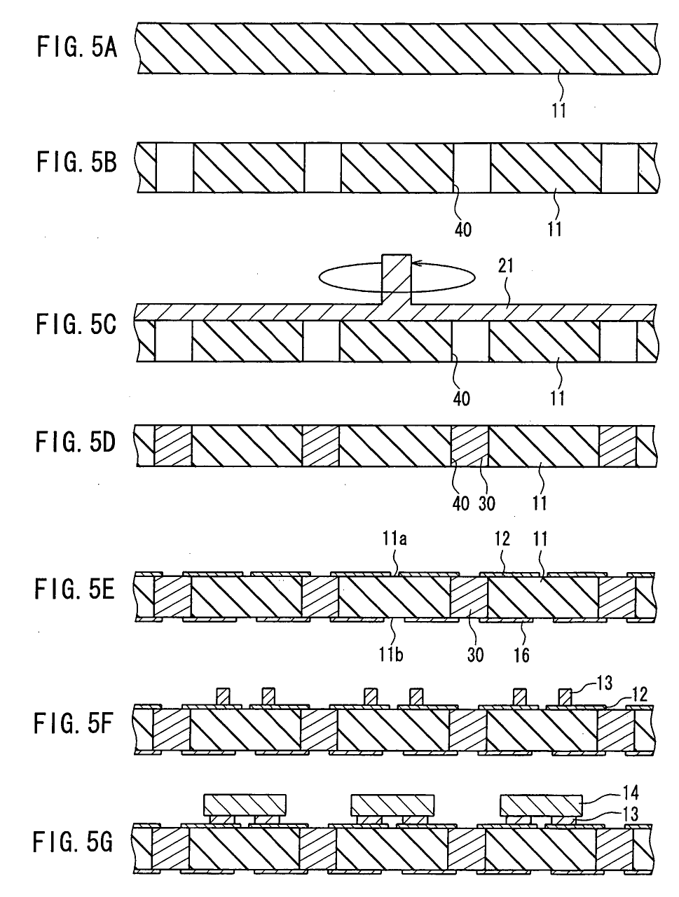

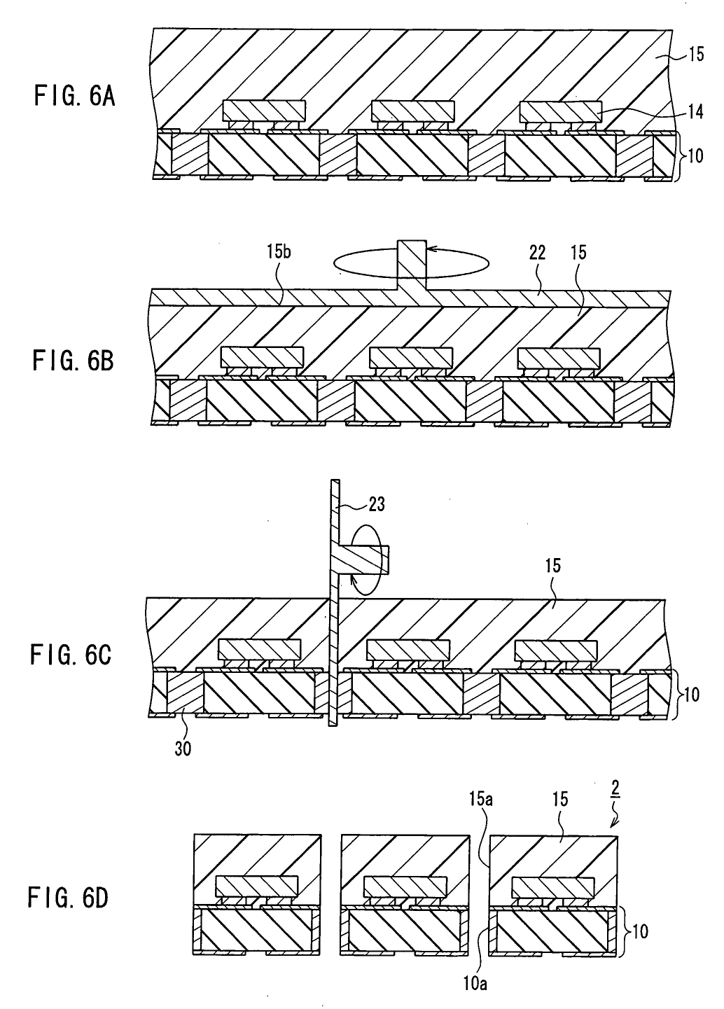

Next, a method for manufacturing the light-emitting device 2 of Embodiment 2 of the present invention will be described by appropriately referring to the drawings. FIGS. 5A to 5G and 6A to 6D are cross-sectional views showing the processes of a method for manufacturing the light-emitting device 2 of Embodiment 2. The same components as those in FIGS. 2 to 4 are denoted by the same reference numerals, and the explanation will be not repeated.

First, the base material 11 is prepared in FIG. 5A. As the base material 11, e.g., a ceramic sheet having a thickness of about 500 μm without sintering can be used. Then, through grooves 40 are formed in the base material 11 by punching or the like, as shown in FIG. 5B. The width of the through grooves 40 may be, e.g., about 200 to 1000 μm. The length of the through grooves 40 may be, e.g., about 0.1 to 1.5 mm. Subsequently, the base material 11 is sintered at about 1600 to 1800° C.

Next, as shown in FIG. 5C, the base material 11 is polished with the rotary grinder 21 or the like. For example, the polishing may be performed to the extent that the thickness of the base material 11 is about 100 to 300 μm.

As shown in FIG. 5D, the inside of the through grooves 40 is plated with a metallic material such as copper, aluminum or gold, thereby forming the via conductors 30.

As shown in FIG. 5E, the first conductor pattern 12 and the second conductor pattern 16, each of which is connected electrically to the via conductors 30, are formed on the principal surfaces 11a and 11b of the base material 11 by using a well-known photolithography technique.

As shown in FIG. 5F, the bumps 13 made of, e.g., gold are formed on the first conductor pattern 12. Then, as shown in FIG. 5G, the semiconductor light-emitting elements 14 are mounted on the bumps 13.

Next, as shown in FIG. 6A, the phosphor layer 15 having an average thickness of about 500 μm is formed on the substrate 10 to cover the semiconductor light-emitting elements 14. A phosphor paste including a phosphor that emits fluorescence as a result of absorption of light emitted from the semiconductor light-emitting elements 14 and a resin composition that contains a silicone resin or the like may be used to form the phosphor layer 15 by screen printing.

As shown in FIG. 6B, the upper surface 15b of the phosphor layer 15 is polished with the rotary grinder 22 or the like. For example, the polishing may be performed to the extent that the thickness of the phosphor layer 15 is about 200 to 300 μm.

Then, the phosphor layer 15 and the substrate 10 are cut out at the same time along the via conductors 30 with the rotating blade 23 or the like, as shown in FIG. 6C. Thus, individual light-emitting devices 2 are provided, as shown in FIG. 6D. This method easily can provide the light-emitting device 2 in which the side 15a of the phosphor 15 and the side 10a of the substrate 10 are connected continuously.

### Embodiment 3

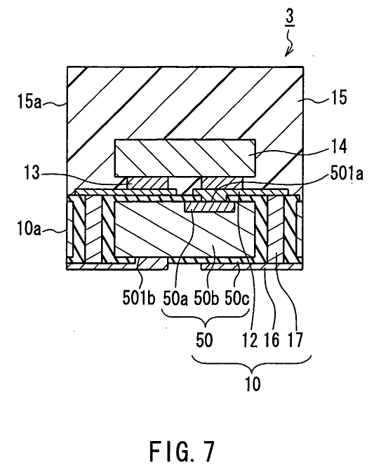

A light-emitting device of Embodiment 3 of the present invention will be described with reference to the drawings. FIG. 7 is a cross-sectional view showing the light-emitting device of Embodiment 3. The same components as those in FIG. 1 are denoted by the same reference numerals, and the explanation will not be repeated.

The light-emitting device 3 of Embodiment 3 differs from the light-emitting device 1 of Embodiment 1 only in the configuration of the base material. As shown in FIG. 7, a base material 50 of the light-emitting device 3 includes a first conductive-type (e.g., p-type) region 50a that is in contact with the first conductor pattern 12, and a second conductive-type (e.g., n-type) region 50b that is in contact with both the first conductive-type region 50a and the second conductor pattern 16. The base material 50 further includes an electric insulating film 50c made of SiO₂ or the like to maintain electrical insulation between the first conductor pattern 12 and the first and second conductive-type regions 50a, 50b, between the second conductive-type region 50b and the via conductors 17, and between the second conductive-type region 50b and the second conductor pattern 16. The electric insulating film 50c is not formed between part of a principal surface 501a of the first conductive-type region 50a and the first conductor pattern 12 and between part of a principal surface 501b of the second conductive-type region 50b and the second conductor pattern 16. In the light-emitting device 3, the first conductive-type region 50a and the second conductive-type region 50b constitute a Zener diode. Therefore, if a high voltage such as static electricity is applied to the semiconductor light-emitting element 14, it can be protected by the Zener diode.

Like the light-emitting device 1 of Embodiment 1, a side 15a of the phosphor layer 15 and a side 10a of the substrate 10 are connected continuously in the light-emitting device 3. Thus, the light-emitting device 3 also can suppress color non-uniformity of light to be produced.

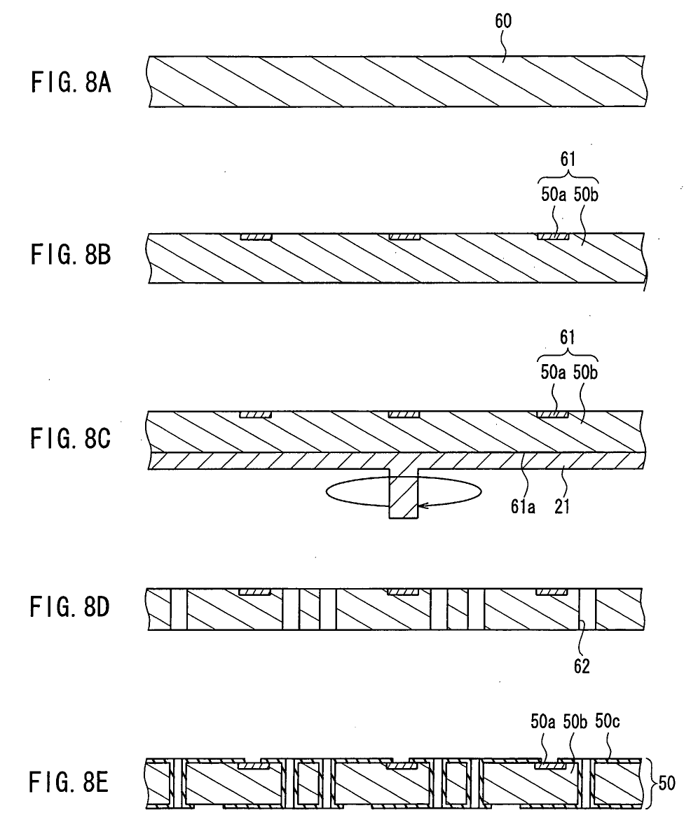

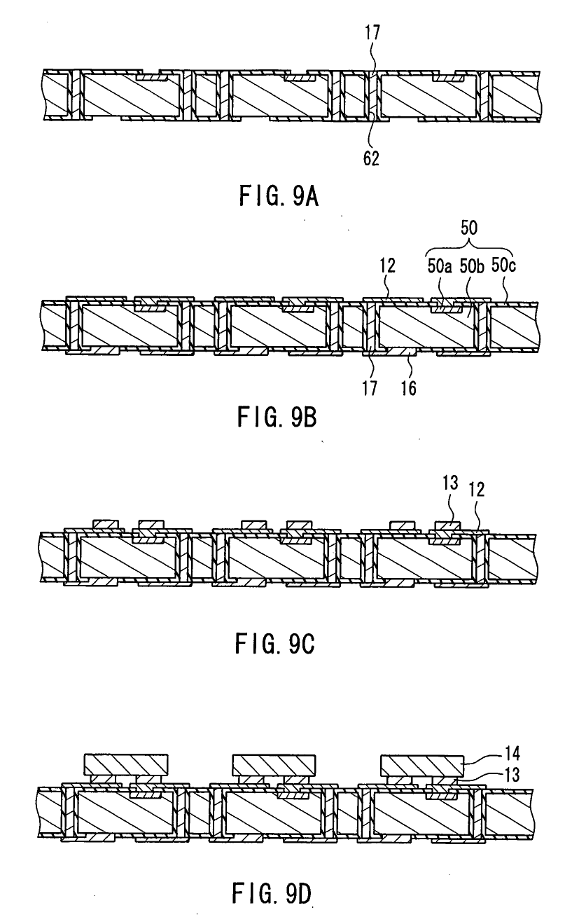

Next, a method for manufacturing the light-emitting device 3 of Embodiment 3 of the present invention will be described by appropriately referring to the drawings. FIGS. 8A to 8E and 9A to 9D are cross-sectional views showing the processes of a method for manufacturing the light-emitting device 3 of Embodiment 3. The same components as those in FIGS. 2 and 7 are denoted by the same reference numerals, and the explanation will not be repeated.

First, a semiconductor substrate 60 is prepared in FIG. 8A. As the semiconductor substrate 60, e.g., an n-type silicon wafer having a thickness of about 500 μm can be used. Then, as shown in FIG. 8B, a p-type dopant is added to part of a principal surface of the semiconductor substrate 60, so that the p-type (first conductive-type) regions 50a are formed. In this manner, it is possible to provide a diode substrate 61 including the p-type regions 50a and the n-type (second conductive-type) region 50b.

Next, as shown in FIG. 8C, a principal surface 61a of the diode substrate 61 that is opposite to the principal surface in which the p-type regions 50a are formed is polished with the rotary grinder 21 or the like. For example, the polishing may be performed to the extent that the thickness of the diode substrate 61 is about 100 to 300 μm.

As shown in FIG. 8D, via holes 62 are formed in the diode substrate 61 by dry etching or the like. The diameter of the via holes 62 may be, e.g., about 200 to 300 μm.

As shown in FIG. 8E, the electric insulating film 50c is formed on the inner wall of each of the via holes 62 and predetermined positions of both principal surfaces of the diode substrate 61 by chemical vapor deposition (CVD) or the like. Thus, the base material 50 including the p-type regions 50a, the n-type region 50b, and the electric insulating film 50c is provided.

As shown in FIG. 9A, the inside of the via holes 62 is plated with a metallic material such as copper, aluminum or gold, thereby forming the via conductors 17.

As shown in FIG. 9B, the first conductor pattern 12 and the second conductor pattern 16, each of which is connected electrically to the via conductors 17, are formed on both principal surfaces of the base material 50 by using a well-known photolithography technique.

As shown in FIG. 9C, the bumps 13 made of, e.g., gold are formed on the first conductor pattern 12. Then, as shown in FIG. 9D, the semiconductor light-emitting elements 14 are mounted on the bumps 13. The subsequent processes are the same as those in the manufacturing method (FIGS. 3A to 3C) of the light-emitting device 1 of Embodiment 1, and the explanation will be not repeated.

### Embodiment 4

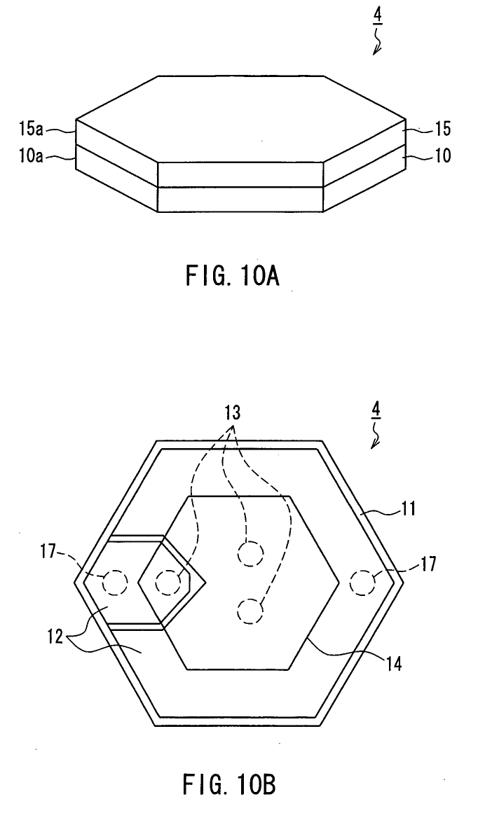

A light-emitting device of Embodiment 4 of the present invention will be described with reference to the drawings. FIG. 10 illustrates the light-emitting device of Embodiment 4: FIG. 10A is a schematic perspective view showing the light-emitting device of Embodiment 4; and FIG. 10B is a schematic top view showing the arrangement of components of the light-emitting device of Embodiment 4. FIG. 10B does not include a phosphor layer. The same components as those in FIG. 1 are denoted by the same reference numerals, and the explanation will not be repeated.

The light-emitting device 4 of Embodiment 4 differs from the light-emitting device 1 of Embodiment 1 only in the shapes of the substrate, the phosphor layer, and the semiconductor light-emitting element. As shown in FIGS. 10A and 10B, the substrate 10, the phosphor layer 15, and the semiconductor light-emitting element 14 of the light-emitting device 4 are a substantially regular hexagon in shape. This configuration can reduce the anisotropy of light emitted from the phosphor layer 15.

Like the light-emitting device 1 of Embodiment 1, a side 15a of the phosphor layer 15 and a side 10a of the substrate 10 are connected continuously in the light-emitting device 4. Thus, the light-emitting device 4 also can suppress color non-uniformity of light to be produced. The shape of the semiconductor light-emitting element 14 of the light-emitting device 4 is a substantially regular hexagon, but may be a substantially square as in the case of Embodiments 1 to 3.

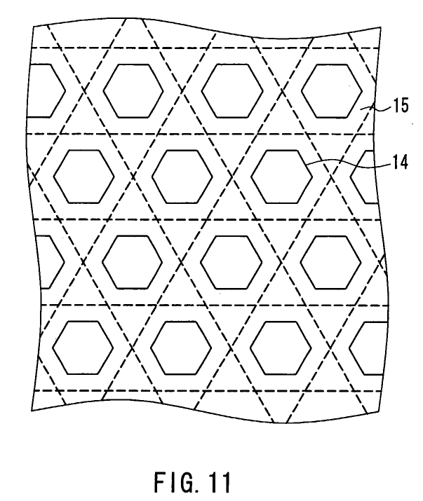

The hexagonal shape can be obtained by cutting out the phosphor layer 15 and the substrate 10 at the same time along the broken lines of FIG. 11 with the rotating blade 23 in the same manner as the process (FIG. 3C) of the manufacturing method of the light-emitting device 1. FIG. 11 does not include the components other than the semiconductor light-emitting elements 14 and the phosphor layer 15.

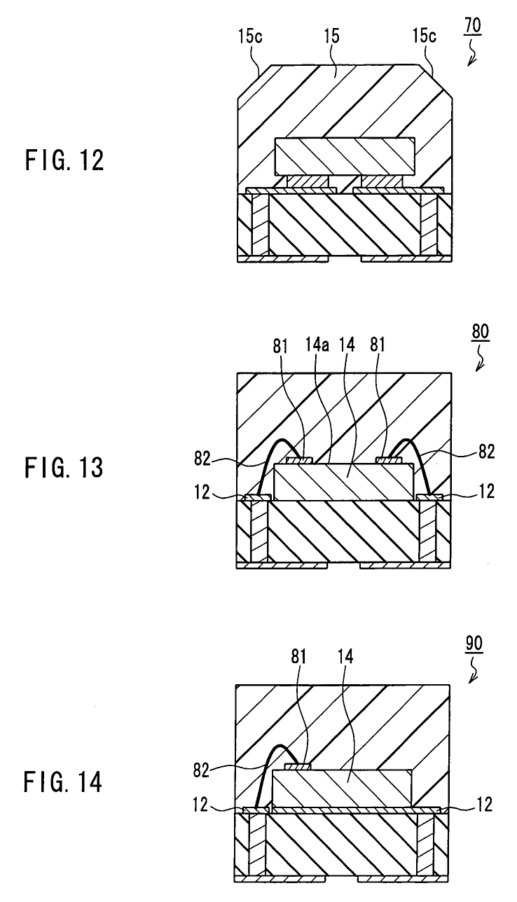

The light-emitting device of the present invention has been described by way of embodiments, but the present invention is not limited to those embodiments. For example, either the side of the phosphor layer or the side of the substrate may be an inclined plane. In the case of a light-emitting device 70 as shown in FIG. 12, corners 15c of the phosphor layer 15 may be chamfered for color matching of light to be produced. Moreover, in the case of a light-emitting device 80 as shown in FIG. 13, the semiconductor light-emitting element 14 and the first conductor pattern 12 may be connected electrically via electrodes 81 formed on an upper surface 14a of the semiconductor light-emitting element 14 and bonding wires 82. Alternatively, in the case of a light-emitting device 90 as shown in FIG. 14, the semiconductor light-emitting element 14 may be fixed on the first conductor pattern 12 made of silver paste or the like, instead of not using part of the electrodes 81 and part of the bonding wires 82. The light-emitting devices 70, 80, and 90 have the same configuration as the light-emitting device 1 of Embodiment 1 except for the above features.

### Embodiment 5

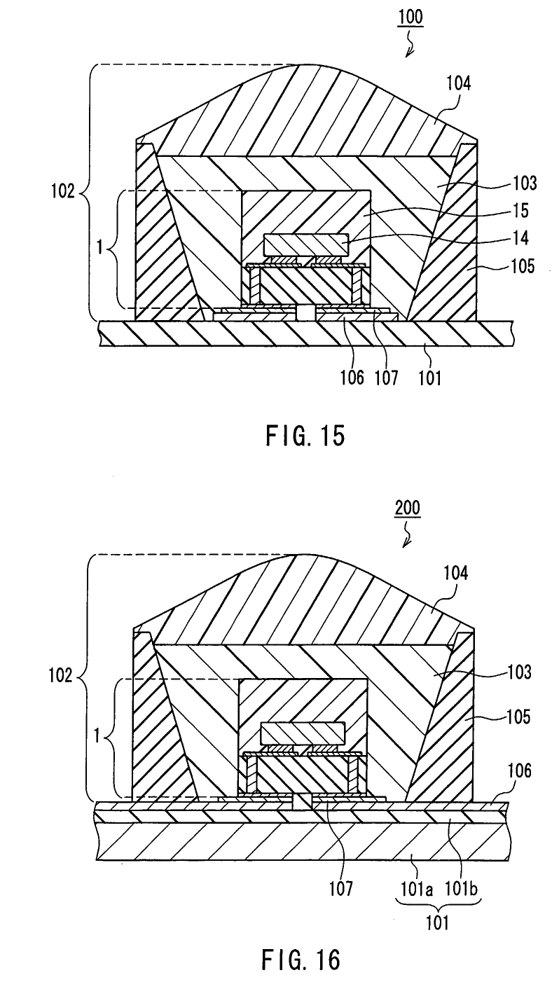

A light-emitting module of Embodiment 5 of the present invention will be described by appropriately referring to the drawings. FIG. 15 is a cross-sectional view showing the light-emitting module of Embodiment 5. The light-emitting module of Embodiment 5 includes the light-emitting device 1 of Embodiment 1. The same components as those in FIG. 1 are denoted by the same reference numerals, and the explanation will not be repeated.

As shown in FIG. 15, the light-emitting module 100 of Embodiment 5 includes a main substrate 101 made of a ceramic material such as AlN or alumina and a plurality of light-emitting units 102 (although FIG. 15 shows a single unit) formed on the main substrate 101.

The light-emitting unit 102 includes the light-emitting device 1, a sealing resin layer 103 for sealing the light-emitting device 1, a lens 104 formed on the sealing resin layer 103, and a reflecting plate 105 for reflecting light emitted from the light-emitting device 1. Moreover, a conductor pattern 106 is formed on the main substrate 101, and the light-emitting device 1 is mounted on the conductor pattern 106 via solder 107. In addition to the solder 107, e.g., a mounting method utilizing Au—Sn eutectic bonding or Ag paste also can be used.

The light-emitting module 100 with this configuration includes the light-emitting device 1 of the present invention and thus can suppress color non-uniformity of light to be produced. In the light-emitting module 100, the sealing resin layer 103 and the lens 104 may be formed of a transparent resin such as a silicone resin or epoxy resin. The material of the reflecting plate 105 may be, e.g., a composite material obtained by coating the surface of metal having a high reflectance such as aluminum with a resin, or a ceramic material having a high-reflectance such as alumina. In particular, the ceramic material is preferred because the reflecting plate 105 can be formed integrally with the main substrate 101. This embodiment uses the light-emitting device 1 of Embodiment 1, but the present invention is not limited thereto. For example, any of the light-emitting devices 2 to 4 of Embodiments 2 to 4 also can be used.

### Embodiment 6

A light-emitting module of Embodiment 6 of the present invention will be described by appropriately referring to the drawings. FIG. 16 is a cross-sectional view showing the light-emitting module of Embodiment 6. The light-emitting module of Embodiment 6 includes the light-emitting device 1 of Embodiment 1. The same components as those in FIG. 15 are denoted by the same reference numerals, and the explanation will not be repeated.

The light-emitting module 200 of Embodiment 6 differs from the light-emitting module 100 of Embodiment 5 only in the configuration of the main substrate 101. As shown in FIG. 16, the main substrate 101 of the light-emitting module 200 includes a metal layer 101a made of aluminum or the like and an electric insulating layer 101b formed on the metal layer 101a. The electric insulating layer 101b may be, e.g., a composite sheet including 70 to 95 wt % of inorganic filler and 5 to 30 wt % of thermosetting resin composition. Like the light-emitting module 100 of Embodiment 5, the light-emitting module 200 also includes the light-emitting device 1 of the present invention and thus can suppress color non-uniformity of light to be produced.

### Embodiment 7

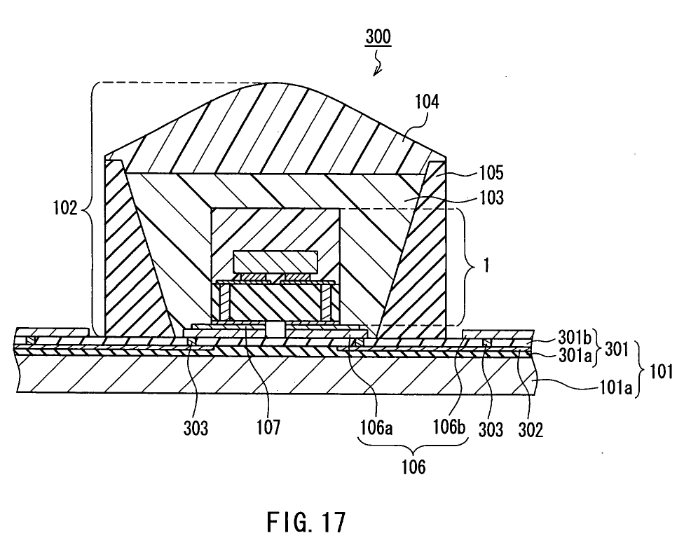

A light-emitting module of Embodiment 7 of the present invention will be described by appropriately referring to the drawings. FIG. 17 is a cross-sectional view showing the light-emitting module of Embodiment 7. The light-emitting module of Embodiment 7 includes the light-emitting device 1 of Embodiment 1. The same components as those in FIG. 16 are denoted by the same reference numerals, and the explanation will not be repeated.

In the light-emitting module 300 of Embodiment 7, as shown in FIG. 17, an electric insulating layer 301 of the main substrate 101 includes a first electric insulating layer 301a formed on the metal layer 101a and a second electric insulating layer 301b formed on the first electric insulating layer 301a. Moreover, an interlayer conductor pattern 302 is arranged between the first electric insulating layer 301a and the second electric insulating layer 301b. The conductor pattern 106 formed on the main substrate 101 includes a conductor pattern 106a located inside the light-emitting unit 102 and a conductor pattern 106b located outside the light-emitting unit 102. The conductor pattern 106a and the conductor pattern 106b are connected electrically via the interlayer conductor pattern 302 and via conductors 303 that pass through the second electric insulating layer 301b. The other configurations are the same as those of the light-emitting module 200 of Embodiment 6. In the light-emitting module 300, it is not necessary to form the reflecting plate 105 on the conductor pattern 106. Therefore, the adhesion between the reflecting plate 105 and the main substrate 101 can be improved. Like the light-emitting modules 100 and 200 of Embodiments 5 and 6, the light-emitting module 300 also includes the light-emitting device 1 of the present invention and thus can suppress color non-uniformity of light to be produced.

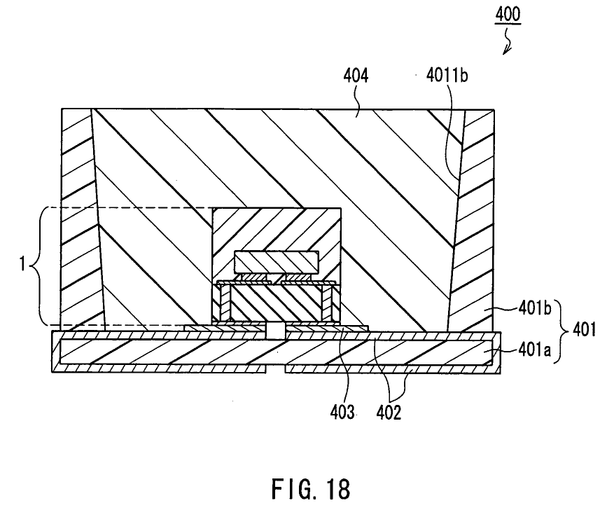

The light-emitting module of the present invention has been described by way of embodiments, but the present invention is not limited to those embodiments. For example, as shown in FIG. 18, a light-emitting module 400 may include the following: a resin package 401 that is made of liquid crystal polymer or polyphthalamide resin and has a base 401a and sloping sides 401b with a hollow 4011b inside; an electrode 402 formed on the surface of the base 401a of the resin package 401; the light-emitting device 1 that is placed in the hollow 4011b of the resin package 401 and mounted on the electrode 402 via solder 403; and a sealing resin layer 404 that is formed in the hollow 4011b and seals the light-emitting device 1. In this case, the light-emitting module 400 is a so-called surface mount device (SMD).

### Embodiment 8

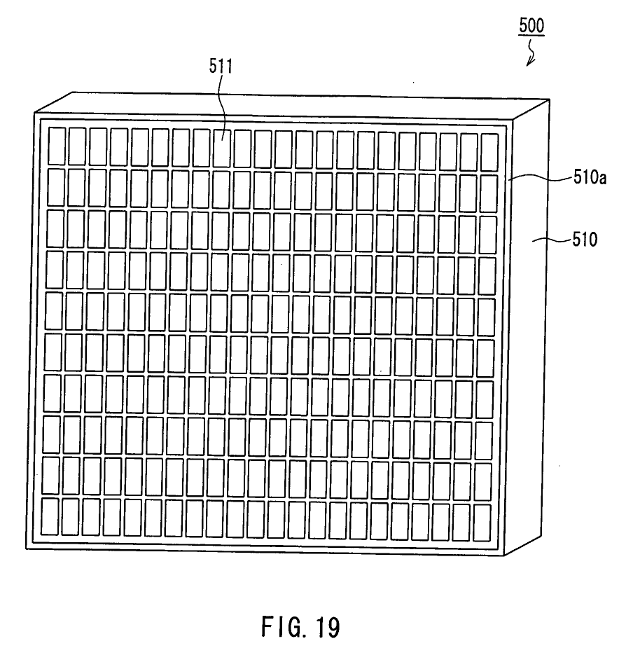

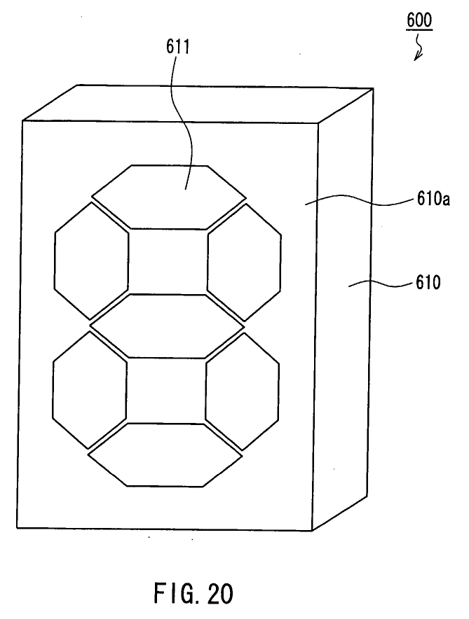

A display unit of Embodiment 8 of the present invention will be described by appropriately referring to the drawings. FIG. 19 is a perspective view showing an image display of Embodiment 8.

As shown in FIG. 19, the image display 500 of Embodiment 8 includes a panel 510. A plurality of light-emitting modules 511 according to any one of Embodiments 5 to 7 are arranged in a matrix form on a principal surface 510a of the panel 510 as light sources. The image display 500 with this configuration uses the light-emitting modules 511, each of which includes the light-emitting device 1 of the present invention, as light sources and thus can suppress color non-uniformity of light to be produced.

### Embodiment 9

A display unit of Embodiment 9 of the present invention will be described by appropriately referring to the drawings. FIG. 20 is a perspective view showing a digital display of Embodiment 9.

As shown in FIG. 20, the digital display 600 of Embodiment 9 includes a frame in the form of a substantially rectangular solid. A plurality of light-emitting modules 611 according to any one of Embodiments 5 to 7 are arranged to make a figure of 8 on a principal surface 610a of the frame 610 as light sources. The digital display 600 with this configuration uses the light-emitting modules 611, each of which includes the light-emitting device 1 of the present invention, as light sources and thus can suppress color non-uniformity of light to be produced.

### Embodiment 10

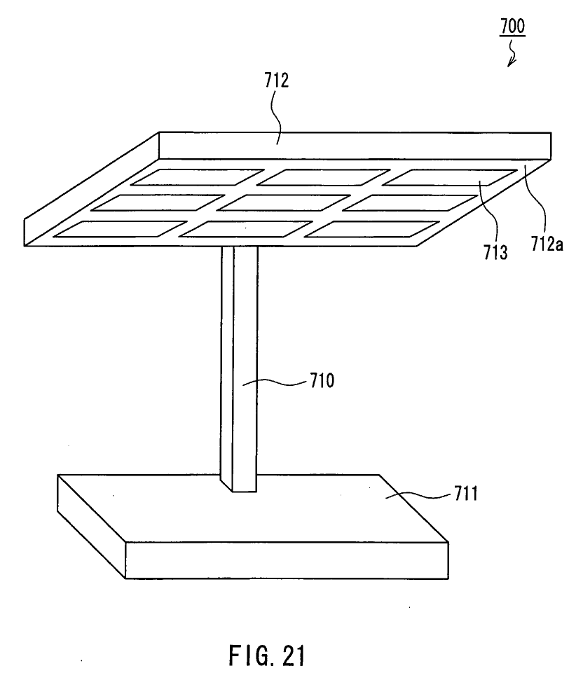

A lighting unit of Embodiment 10 of the present invention will be described by appropriately referring to the drawings. FIG. 21 is a perspective view showing a desktop lamp of Embodiment 10.

As shown in FIG. 21, the desktop lamp 700 of Embodiment 10 includes a neck 710, a base 711 that is fixed at one end of the neck 710 for supporting the neck 710, and a lighting portion 712 that is fixed at the other end of the neck 710. A plurality of light-emitting modules 713 according to any one of Embodiments 5 to 7 are arranged in a matrix form on a principal surface 712a of the lighting portion 712 as light sources. The desktop lamp 700 with this configuration uses the light-emitting modules 713, each of which includes the light-emitting device 1 of the present invention, as light sources and thus can suppress color non-uniformity of light to be produced.

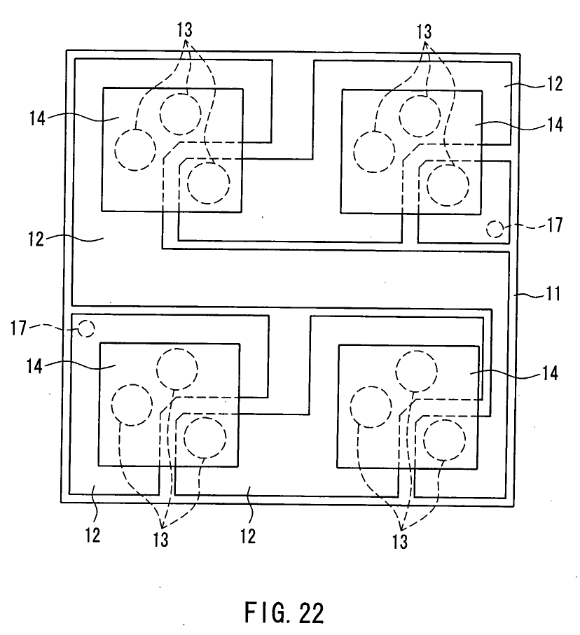

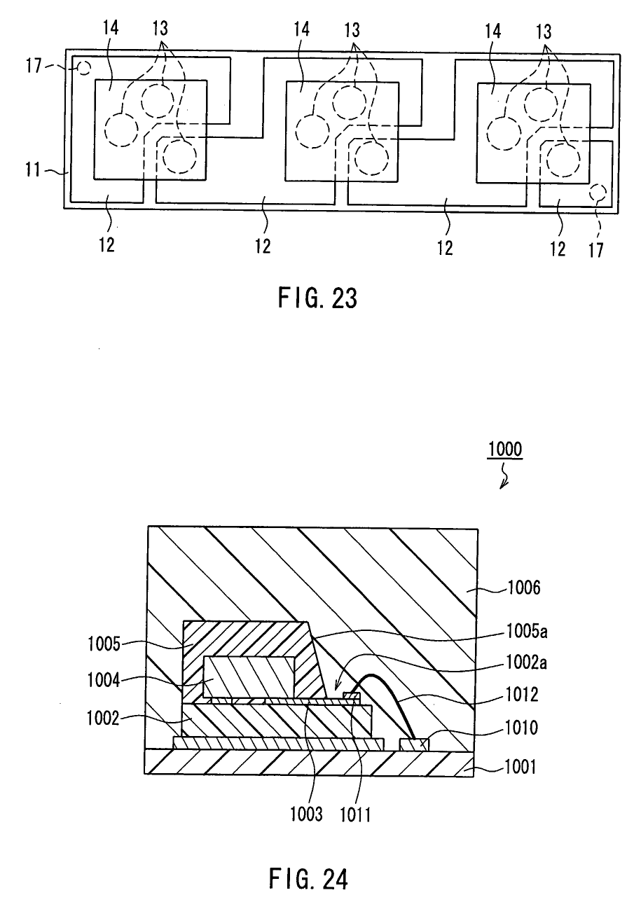

As described above, the present invention has been described by way of embodiments, but the present invention is not limited to those embodiments. For example, the light-emitting device of each of Embodiments 1 to 4 uses only one semiconductor light-emitting element. However, the light-emitting device may include a plurality of semiconductor light-emitting elements 14 formed on the substrate, as shown in FIG. 22 or 23. FIGS. 22 and 23 are schematic top views showing the arrangement of components of the light-emitting device of an embodiment of the present invention. In FIGS. 22 and 23, the same components as those in FIG. 1B are denoted by the same reference numerals, and a phosphor layer is not included.

### INDUSTRIAL APPLICABILITY

The present invention can be applied to a display unit or a lighting unit that can suppress color non-uniformity of light to be produced.

1. A light-emitting device comprising:
a substrate that comprises a base material and a first conductor pattern formed on one principal surface of the base material;
a semiconductor light-emitting element that is mounted on the first conductor pattern; and
a phosphor layer that is formed on the substrate to cover the semiconductor light-emitting element and emits fluorescence as a result of absorption of light emitted from the semiconductor light-emitting element,
wherein a side of the phosphor layer and a side of the substrate are connected continuously.

2. The light-emitting device according to claim 1, wherein the substrate further comprises a second conductor pattern formed on the other principal surface of the base material that is opposite to the one principal surface, and via conductors formed in a thickness direction of the base material for electrically connecting the first conductor pattern and the second conductor pattern.

3. The light-emitting device according to claim 2, wherein the via conductors are formed along sides of the base material.

4. The light-emitting device according to claim 2, wherein the base material comprises a first conductive-type region that is in contact with the first conductor pattern, and a second conductive-type region that is in contact with both the first conductive-type region and the second conductor pattern.

5. A light-emitting module comprising:
the light-emitting device according to claim 1; and
a main substrate on which the light-emitting device is mounted.

6. A display unit comprising:
the light-emitting module according to claim 5 as a light source.

7. A lighting unit comprising:
the light-emitting module according to claim 5 as a light source.

8. A method for manufacturing a light-emitting device comprising:
mounting a semiconductor light-emitting element on a conductor pattern of a substrate that comprises a base material, with the conductor pattern being formed on one principal surface of the base material;
forming a phosphor layer that emits fluorescence as a result of absorption of light emitted from the semiconductor light-emitting element on the substrate so as to cover the semiconductor light-emitting element; and
cutting out the phosphor layer and the substrate at the same time so that a side of the phosphor layer and a side of the substrate are connected continuously.
